(19) United States
(12) Patent Application Publication
(10) Pub. No.: US 2026/0322359 A1
(43) Pub. Date: Oct. 15, 2026

(54) POWER FILTER CIRCUIT

(71) Applicant: Radial Engineering Ltd., Port Coquitlam (CA)

(72) Inventors: William Craig Hutchison, Port Coquitlam (CA); Emily Swan, Port Coquitlam (CA); Jacobus Van Eeden, Port Coquitlam (CA)

(21) Appl. No.: 19/262,264

(22) Filed: Jul. 8, 2025

(30) Foreign Application Priority Data
Apr. 11, 2025 (CA) 3270660

(51) Int. Cl. H03H 11/48; H03F 1/34; H03F 3/45; H03H 11/12

(52) U.S. Cl. CPC H03H 11/481; H03F 1/34; H03F 3/45475; H03H 11/1204; H03F 2200/372; H03F 2200/93; H03F 2203/45138

(57) ABSTRACT

Power filter circuits and methods of operating the power filter circuits are described. A power filter circuit comprises a capacitance multiplier configured to receive an input signal from a power supply. The capacitance multiplier includes a low-pass filter and at least one Darlington pairs sub-circuit comprising two transistors. A feedback network provides alternating current (AC)-coupled negative feedback from an output node of the capacitance multiplier to a base node of at least one of the two transistors in the Darlington pairs sub-circuit. The AC-coupled negative feedback enhances noise rejection, enabling the power filter circuit to provide a filtered output signal with reduced noise and impedance.

### FIELD

The present disclosure relates to power filter circuits and, more particularly, to direct current (DC) power filter circuits incorporating capacitance multipliers including Darlington pairs.

### BACKGROUND

Linear power supplies are widely used to convert alternating current (AC) from a wall outlet into DC at a specified voltage level. These power supplies typically employ a transformer to step down the input voltage, followed by rectification and filtering stages to reduce ripple and noise. While they provide a relatively stable DC output, their performance can be affected by ripple, noise, and limited load regulation, which may impact sensitive analog circuits.

Switching power supplies, on the other hand, have gained popularity due to their ability to operate efficiently across a wide range of input voltages. They achieve voltage regulation by rapidly switching the input current at high frequencies, allowing for smaller components and more compact designs. However, the inherent switching nature introduces high-frequency noise and harmonics, which may propagate into the output and affect downstream circuits.

Noise and impedance in power supplies are considerations for applications involving sensitive analog or low-distortion circuits. High noise levels or variations in power supply voltage can degrade the performance of these circuits, causing unwanted artifacts and distortions.

Thus, there remains a need for a power filter circuit that effectively reduces ripple, noise, and impedance to enhance the performance of downstream circuits.

### SUMMARY

In one aspect, the present disclosure provides a power filter circuit comprising: a capacitance multiplier configured to receive an input signal from a power supply, the capacitance multiplier including: a low-pass filter; and at least one Darlington pairs sub-circuit comprising two transistors; and a feedback network configured to provide alternating current (AC)-coupled negative feedback from an output node of the capacitance multiplier to a base node of at least one of the two transistors in the Darlington pairs sub-circuit to enhance noise rejection in an output signal of the power filter circuit.

According to an embodiment, the low-pass filter may comprise a plurality of resistors and a plurality of capacitors arranged to form a multi-pole low-pass filter.

According to an embodiment, the feedback network may be configured to provide the AC-coupled negative feedback to respective base nodes of the two transistors of the at least one Darlington pairs sub-circuit.

According to an embodiment, the feedback network may comprise at least one amplifier configured to amplify an AC component from the output node of the capacitance multiplier and inject the amplified AC component into the base node of the at least one of the two transistors in the Darlington pairs sub-circuit.

According to an embodiment, the feedback network may comprise a coupling capacitor configured to pass the AC component from the output node of the capacitance multiplier to the amplifier.

According to an embodiment, the amplifier may comprise an operational amplifier or an amplification stage formed from discrete components.

According to an embodiment, the amplifier may be biased with a direct current (DC) using at least one of: a Zener diode, a light-emitting diode (LED), or a shunt voltage reference.

According to an embodiment, the power filter circuit may comprise a positive half and a negative half, each of the positive half and the negative half connecting to the power supply and including its corresponding capacitance multiplier and feedback network.

According to an embodiment, the feedback network may further comprise an amplification sub-circuit that is powered by a positive supply voltage from the output node of the positive half and a negative supply voltage from the output node of the negative half.

According to an embodiment, the amplification sub-circuit may comprise a dual operational amplifier in parallel with two capacitors connected in series, a junction of the two capacitors being grounded.

According to an embodiment, the amplification sub-circuit may comprise two operational amplifiers each being in parallel with a capacitor, a junction of the two operational amplifiers being grounded.

According to an embodiment, the feedback network may comprise at least one amplifier configured to amplify an AC component directly from a load of the power filter circuit through a remote sense line and a coupling capacitor, and inject the amplified AC component into the base node of the at least one of the two transistors in the Darlington pairs sub-circuit.

In another aspect, the present disclosure provides a method of operating a power filter circuit, the method comprising: feeding an input signal from a power supply to a capacitance multiplier of the power filter circuit, the capacitance multiplier including a low-pass filter and at least one Darlington pairs sub-circuit comprising two transistors; processing the input signal through the low-pass filter and the at least one Darlington pairs sub-circuit to generate a filtered signal; providing the filtered signal at an output node of the capacitance multiplier to a feedback network of the power filter circuit to generate an AC-negative feedback; and applying the AC-negative feedback to a base node of at least one of the two transistors in the at least one Darlington pairs sub-circuit to enhance noise rejection in an output signal of the power filter circuit.

According to an embodiment, the low-pass filter may comprise a plurality of resistors and a plurality of capacitors arranged to form a multi-pole low-pass filter.

According to an embodiment, the method may further comprise applying the AC-coupled negative feedback to respective base nodes of the two transistors in the Darlington pairs sub-circuit.

According to an embodiment, the method may further comprise: amplifying an AC component of the filtered signal, from the output node of the capacitance multiplier, using an amplifier in the feedback network; and injecting the amplified AC component into the base node of at least one of the two transistors in the Darlington pairs sub-circuit.

According to an embodiment, the method may further comprise: passing the AC component of the filtered signal through a coupling capacitor to the amplifier in the feedback network.

According to an embodiment, the method may further comprise: biasing the amplifier with a DC using at least one of: a Zener diode; a light-emitting diode (LED); or a shunt voltage reference.

According to an embodiment, the power filter circuit may comprise a positive half and a negative half, each of the positive half and the negative half connecting to the power supply and including its corresponding capacitance multiplier and feedback network.

According to an embodiment, the method may further comprise: amplifying an AC component of the filtered signal, directly from a load of the power filter circuit through a remote sense line and a coupling capacitor, using an amplifier in the feedback network; and injecting the amplified AC component into the base node of at least one of the two transistors in the Darlington pairs sub-circuit.

Other aspects and features of the present invention will become apparent to those of ordinary skill in the art upon review of the following description of specific embodiments of the invention in conjunction with the accompanying claims.

### BRIEF DESCRIPTION OF THE DRAWINGS

In drawings which illustrate embodiments of the disclosure,

FIG. 1 shows a configuration of an example capacitance multiplier (prior art).

FIG. 2 shows another configuration of an example capacitance multiplier (prior art).

FIG. 3 shows yet another configuration of an example capacitance multiplier circuit (prior art).

FIG. 4 shows an example configuration of a power filter circuit involving Darlington pairs according to an implementation of the present disclosure.

FIG. 5 shows a first variant configuration of a power filter circuit involving Darlington pairs according to an implementation of the present disclosure.

FIG. 6 shows a second variant configuration of a power filter circuit involving Darlington pairs according to an implementation of the present disclosure.

FIG. 7 shows a third variant configuration of a power filter circuit involving Darlington pairs according to an implementation of the present disclosure.

FIG. 8 shows a fourth variant configuration of a power filter circuit involving Darlington pairs according to an implementation of the present disclosure.

FIG. 9 shows a fifth variant configuration of a power filter circuit involving Darlington pairs according to an implementation of the present disclosure.

FIG. 10 shows a sixth variant configuration of a power filter circuit involving Darlington pairs according to an implementation of the present disclosure.

FIG. 11 shows an example of the measured voltage noise performance of a circuit according to an implementation of the present disclosure.

### DETAILED DESCRIPTION

In the context of the present disclosure, various terms are used in accordance with what is understood to be the ordinary meaning of those terms.

The quality of a power supply allows electronic circuits to operate reliably, especially in applications that require high performance and low noise. Linear power supplies are a standard choice for providing stable DC voltage by rectifying and filtering AC power. Their simple design using transformers and capacitors has made them a reliable option for decades. However, inherent limitations such as ripple and noise can affect the performance of sensitive analog circuits. Switching power supplies, on the other hand, offer advantages in efficiency and compactness. By operating at high switching frequencies, these supplies enable smaller component sizes and versatile voltage regulation. Despite these benefits, high-frequency switching inherently introduces noise and harmonics that can propagate into downstream circuits and degrade their performance. In addition, the regulation of multiple outputs is often inaccurate, with load variations on unsensed outputs causing voltage instability.

Low-noise, low-distortion analog circuits are sensitive to variations in power supply quality. Noise and ripple on the supply rails can couple into signal paths, degrading performance through artifacts and distortion. Similarly, moderate impedance and poor load regulation can exacerbate these problems by introducing dynamic voltage variations that affect circuit operation, particularly in applications with fluctuating load requirements.

The challenges associated with both linear and switching power supplies highlight the need for a more robust solution. A power filter circuit is desired that is capable of reducing ripple, noise, and impedance to provide cleaner power to sensitive circuits. It is also desired that such a solution seamlessly integrates with existing power supply architectures to provide a practical and cost-effective means of improving circuit performance.

The present disclosure introduces an electronic circuit that combines a capacitance multiplier with AC-coupled negative feedback to create a low-pass filter capable of effectively reducing noise from conventional linear or switching power supplies. This circuit addresses the challenge of providing low-noise, clean DC power to sensitive analog circuits while maintaining low output impedance and high stability. The disclosed designs integrate transistors arranged as Darlington pairs and operational amplifiers (op-amps) for negative feedback to achieve improved line and load regulation with minimal voltage drop.

One of the various aspects of the disclosure is the use of Darlington pairs to increase current gain and effective capacitance multiplication, so as to enable the circuit to handle medium or high current outputs. This configuration also allows for the implementation of various forms of capacitance multipliers, ranging from single-pole resistor-capacitor combinations to more advanced multi-pole filters incorporating inductors, resistors, and capacitors. Some implementations may utilize four poles of filtering to provide enhanced noise rejection across a wide frequency range.

Some implementations may employ inverting amplifiers in the negative feedback path, in which low-noise op-amps may be advantageous for their convenience and cost-effectiveness. Discrete inverting amplifiers may also be used as an alternative, depending on the design requirements. The disclosure supports the use of both single and dual op-amp packages, and multiple methods for establishing low-noise DC biasing of the amplifiers are described to provide improved performance and stability.

In some implementations, remote sensing lines may be integrated in both positive and negative voltage configurations. This may allow feedback to be taken directly from the load to reduce the impedance effects of PCB traces and further improve the filtering performance as experienced by the load. This approach may enhance voltage stability and compensate for current-draw-induced variations.

As a result, the disclosed power filter is not a traditional voltage regulator designed to provide a fixed output voltage. Instead, it smooths and follows the input voltage, typically regulated by upstream components, with a minimal voltage drop of less than 2 volts. This makes it well-suited for applications requiring clean, low-noise power with medium to high current capability. Additionally, some implementations provide a controlled ramp-up or soft-start functionality during power-on, which reduces initial transients and thus prolongs the lifetime of connected components.

Various embodiments are described in the following to address specific application needs, including circuits with single and dual feedback paths, positive and negative voltage configurations, and different methods of capacitance multiplier implementation. These design variations provide flexibility in tailoring the circuit to the desired performance, cost, and manufacturing considerations, making it applicable to a wide range of electronic systems.

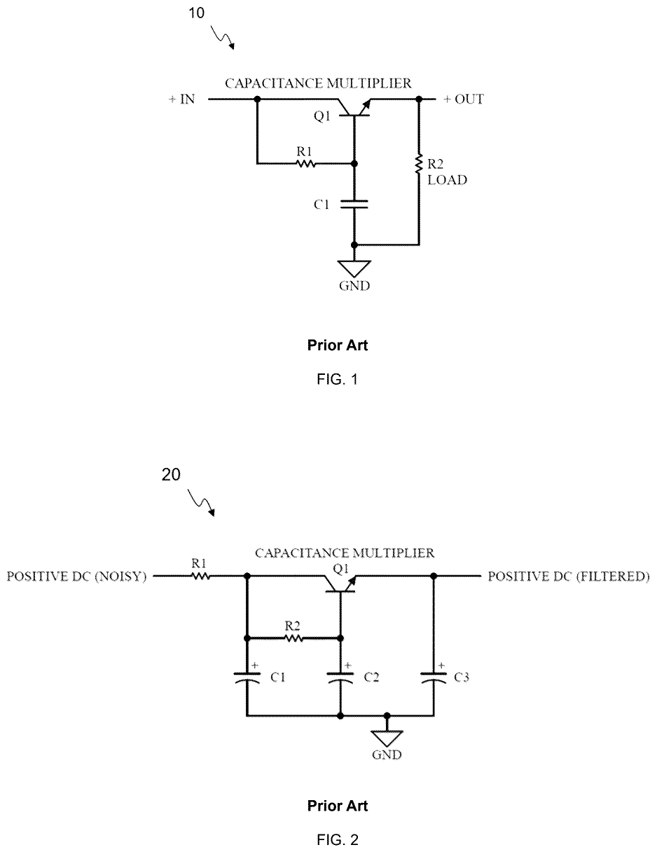

FIG. 1 illustrates a capacitance multiplier circuit 10, which is an existing design. The circuit comprises an input terminal, an output terminal, a ground connection, a transistor, a resistor, and a capacitor. The components are connected as follows.

The input terminal (+IN) is connected to the collector of transistor Q1. The input terminal (+IN) is connected to one end of resistor R1. The other end of resistor R1 is connected to one terminal of capacitor C1, and they are both connected to the base of transistor Q1. The second terminal of capacitor C1 is connected to the ground (GND). The emitter of transistor Q1 is connected directly to the output terminal (+OUT) and also to one end of a load resistor, designated as R2. The other end of the load resistor R2 is connected to the ground.

This configuration forms a capacitance multiplier, where the effective capacitance seen by the load is the value of capacitor C1 multiplied by approximately (β+1), where β is the current gain of the transistor Q1. This arrangement effectively reduces noise and ripple in the output current by leveraging the multiplication effect of the transistor's current gain. The load connected at the output terminal benefits from a stabilized output, as the capacitance value is effectively much larger than the actual capacitance of C1.

It should be understood that, although an NPN transistor (Q1) is used in this example to implement the capacitance multiplier circuit 10, other types of transistors, such as PNP transistors, MOSFETs, or JFETs, can also be used to achieve similar functionality. The choice of transistor type may depend on the specific application requirements, such as voltage, current handling capabilities, and desired frequency response. The principles of the capacitance multiplier circuit remain applicable regardless of the type of transistor used. This consideration regarding the choice of transistor type applies uniformly to all examples described in the description.

In subsequent examples (except for FIG. 10), the load resistor will not be explicitly shown but will be implied in the circuit representation.

FIG. 2 illustrates another example of a capacitance multiplier circuit 20, which is also an existing design. The circuit comprises an input terminal, an output terminal, a ground connection, a transistor, resistors, and capacitors. The circuit 20 is configured to form a two-pole filter, with an additional capacitor acting as a current reservoir to further stabilize the output. The connections between the components are described below.

The input terminal, labeled as “Positive DC (Noisy)”, is connected to one end of resistor R1. The other end of resistor R1 is connected to the collector of transistor Q1 and to one terminal of capacitor C1. The second terminal of capacitor C1 is connected to the ground (GND). Resistor R2 is connected between the base of transistor Q1 and the connection point of R1 and C1. The emitter of transistor Q1 is connected directly to the output terminal, labeled as “Positive DC (Filtered)”. In addition, a second capacitor, C2, is connected between the base of transistor Q1 and the ground. A third capacitor, C3, is connected between the output terminal and the ground. Capacitor C3 serves as the additional current reservoir to enhance the circuit's ability to filter noise and ripple.

In this configuration, resistor R1 and capacitor C1, in conjunction with the capacitance multiplier formed by transistor Q1 and its associated components, create a two-pole low-pass filter. A two-pole filter refers to an electrical filter design that incorporates two reactive components —such as capacitors or inductors—each contributing a point of attenuation or “pole” in the frequency response. The first pole is formed by the combination of resistor R1 and capacitor C1, while the second pole is created by the interaction of the capacitance multiplier circuit with resistor R2 and capacitor C2. This two-pole design may result in a sharper roll-off of high-frequency noise and ripple compared to a single-pole filter.

The inclusion of the two-pole filter enhances the noise rejection and stability of the circuit. By reducing the amplitude of high-frequency components more effectively, this design allows the output voltage to be cleaner and more stable, making it well-suited for powering sensitive electronic applications that require minimal noise and ripple.

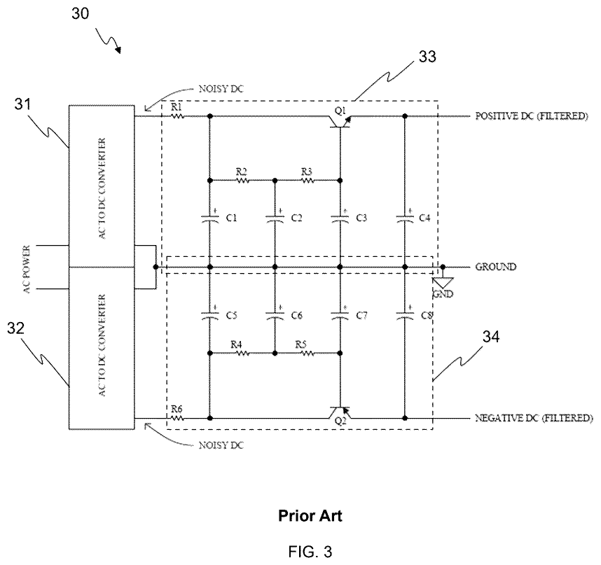

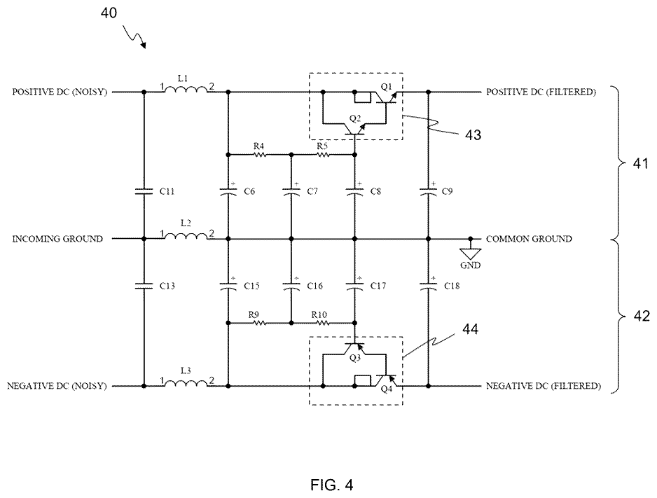

FIG. 3 illustrates yet another example of a capacitance multiplier circuit 30, which includes both positive and negative capacitance multiplier sub-circuits 33, 34 for filtering noise from a power supply. This circuit 30 is designed to further enhance noise filtering and output stability, building upon the principles illustrated in FIG. 2. The figure shows the positive capacitance multiplier sub-circuit 33 for positive DC filtering and the negative capacitance multiplier sub-circuit 34 for negative DC filtering, both of which incorporate additional poles for enhanced noise rejection and impedance reduction. This design may be used with power sources that exhibit significant noise, such as AC to DC converters, DC to DC converters, or linear power supplies.

The positive capacitance multiplier sub-circuit 33 for the positive DC path, an improvement based on the design in FIG. 2, comprises resistors R1, R2, and R3; capacitors C1, C2, C3, and C4; and an NPN transistor Q1. The input to the sub-circuit 33, labeled as “Noisy DC”, is connected to one end of resistor R1. The other end of resistor R1 is connected to the collector of transistor Q1 and to one terminal of capacitor C1. The second terminal of capacitor C1 is connected to the ground. Resistor R2 is connected between the connection point of R1 and C1, and one end of resistor R3. The other end of resistor R3 is connected to the base of transistor Q1. Capacitor C2 is connected between the connection point of R2 and R3, and the ground. Capacitor C3 is connected to the connection point of R3 and the base of transistor Q1, and the ground. The emitter of transistor Q1 is directly connected to the output terminal labeled “Positive DC (Filtered)” and to one terminal of capacitor C4, with the other terminal of C4 connected to the ground.

The configuration of the sub-circuit 33 forms a three-pole low-pass filter, with R1 and C1 forming the first pole and the combination of R2, R3, C2, and C3 collectively forming the second and third poles, resulting in enhanced noise rejection. The emitter of Q1 provides a higher current reflection of the filtered voltage seen at its base, with a voltage drop of approximately 0.6V.

The negative capacitance multiplier sub-circuit 34 for the negative DC path is similarly configured, using a complementary PNP transistor Q2. The input to the sub-circuit 34, labeled as “Noisy DC”, is connected to one end of resistor R6. The other end of resistor R6 is connected to the collector of transistor Q2 and to one terminal of capacitor C5. The second terminal of capacitor C5 is connected to the ground. Resistor R4 is connected between the connection point of R6 and C5, and one end of resistor R5. The other end of resistor R5 is connected to the base of transistor Q2. Capacitor C6 is connected between the connection point of R4 and R5, and the ground. Capacitor C7 is connected to the connection point of R5 and the base of transistor Q2, and the ground. The emitter of transistor Q2 is directly connected to the output terminal labeled “Negative DC (Filtered)” and to one terminal of capacitor C8, with the other terminal of C8 connected to the ground.

Similar to the sub-circuit 33, the configuration of the sub-circuit 34 forms a three-pole low-pass filter, which enhances noise filtering and provides a clean, stable negative DC output.

Both the sub-circuits 33 and 34 are connected to the outputs of AC to DC converters 31 and 32, which serve as the initial power supplies. These converters may produce noise and ripple, so they are unsuitable for sensitive applications without additional filtering. The capacitance multiplier circuit 30 shown in FIG. 3 act as a low-pass filter to reduce noise and ripple while lowering the output impedance.

Building upon the capacitance multiplier circuit 20 illustrated in FIG. 2, the circuit 30 of FIG. 3 achieves enhanced performance by incorporating additional poles in the filtering network and providing both positive and negative voltage filtering paths. However, it should be understood that the capacitance multiplier circuit 10 of FIG. 1 or the capacitance multiplier circuit 20 of FIG. 2 may also be suitable for applications where the added complexity of FIG. 3 is not required, depending on the specific performance requirements.

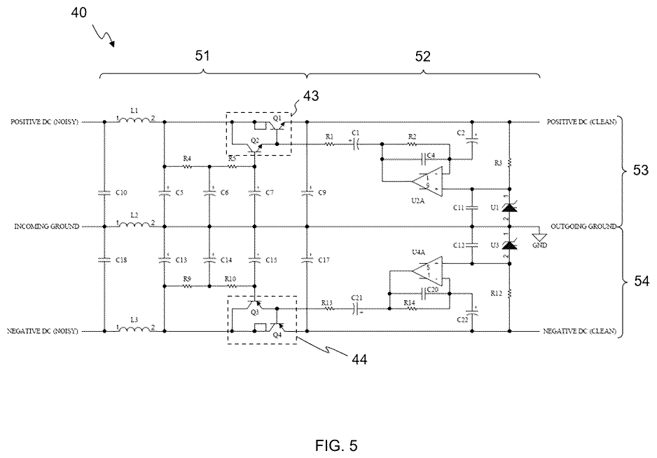

FIG. 4 illustrates an example of a power filter circuit 40 involving Darlington pairs for noise filtering. The circuit 40 incorporates additional inductors, capacitors, and Darlington transistor pairs compared to the example shown in FIG. 3 to achieve a higher-order filtering effect and increased current gain. The circuit 40 is divided into a positive half 41 and a negative half 42. A positive Darlington pairs sub-circuit 43 is used in the positive half 41; a negative Darlington pairs sub-circuit 44 is used in the negative half 42. The connections between the components are detailed as follows.

The positive half 41 is configured to filter and stabilize a noisy positive DC input, labeled as “Positive DC (Noisy)”. The input is connected to one end of inductor L1, which reduces high-frequency noise. The other end of L1 is connected to capacitor C6 and to the input terminal of the positive Darlington pairs sub-circuit 43. On one end, capacitor C11 is connected to the incoming ground, which helps to shunt high-frequency noise; one the other end, capacitor C11 is connected to the positive DC input. Inductor L2 is placed between the incoming ground and the common ground to isolate the ground noise and improve the circuit's overall stability. Capacitors C6, C7, and C8, along with resistors R4 and R5, form a filtering network, which are the same with the filtering network in the sub-circuit 33 of FIG. 3, at the base of the Darlington pair in the positive Darlington pairs sub-circuit 43. Capacitor C9 is connected to the output of the sub-circuit 43 and the common ground, providing additional filtering and acting as a reservoir to stabilize the output, labeled as “Positive DC (Filtered)”.

The negative half 42 is configured to filter and stabilize a noisy negative DC input, labeled as “Negative DC (Noisy)”. The input is connected to one end of inductor L3, which reduces high-frequency noise. The other end of L3 is connected to capacitor C15 and to the input terminal of the negative Darlington pairs sub-circuit 44. On one end, capacitor C13 is connected to the incoming ground, which helps to shunt high-frequency noise; one the other end, capacitor C13 is connected to the negative DC input. Capacitors C15, C16, and C17, along with resistors R9 and R10, form a filtering network, which are the same with the filtering network in the sub-circuit 34 of FIG. 3, at the base of the Darlington pair in the negative Darlington pairs sub-circuit 44. Capacitor C18 is connected to the output of the sub-circuit 44 and the common ground, providing additional filtering and acting as a reservoir to stabilize the output, labeled as “Negative DC (Filtered)”.

In this example, the positive Darlington pairs sub-circuit 43 and the negative Darlington pairs sub-circuit 44 replace the single transistors used in previous examples. As shown, each of the sub-circuits 43, 44 comprises a pair of transistors connected in a Darlington configuration. In the sub-circuit 43, Q1 and Q2 form the Darlington pair for the positive side, while in the sub-circuit 44, Q3 and Q4 form the Darlington pair for the negative side. The Darlington configuration increases the current gain, as the gain of the pair is the product of the gains of the individual transistors (Q1·Q2 or Q3·Q4). This increased gain enhances the effective capacitance multiplication and improves the circuit's 40 ability to filter noise. Additionally, Q1 and Q4 in the Darlington pairs are designed to be medium-or high-current transistors, allowing for higher output current availability and reduced output impedance.

By incorporating inductors L1, L2, and L3, the circuit 40 achieves a four-pole low-pass filter to provide enhanced noise rejection compared to previous examples. The inductors' copper resistance, or direct current resistance (DCR), may also contribute to the filtering effect, particularly at low frequencies. The combination of these improvements allows the outputs —positive and negative DC filtered voltages—to be stable and suitable for applications requiring minimal noise and ripple.

Additionally, inductors L1, L2, and L3, in conjunction with capacitors C6 and C15, form a two-pole low-pass filter prior to the capacitance multiplier. This configuration may help attenuate high-frequency artifacts before the capacitance multiplier stage, so as to improve overall noise filtering. Furthermore, inductor L2 may provide additional high-frequency isolation between the incoming ground and the common ground to reduce unwanted interference that may propagate through the circuit. These enhancements contribute to a cleaner and more stable DC output, particularly in applications where high-frequency noise suppression is desirable.

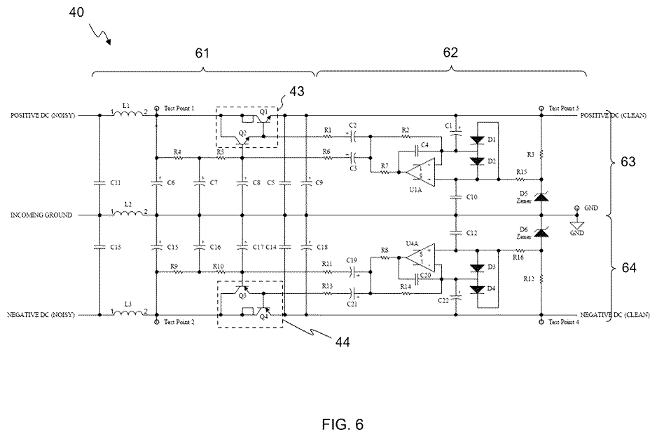

FIG. 5 illustrates a first variant of the power filter circuit 40 involving Darlington pairs for noise filtering. This circuit builds upon the design in FIG. 4 to further improve the aspects related to load regulation by incorporating op-amps to provide AC negative feedback, which further lowers the output impedance of the filter. Like in FIG. 4, the positive half of the circuit is indicated by reference numeral 53, the negative half by reference numeral 54, the positive Darlington pairs sub-circuit by 43, and the negative Darlington pairs sub-circuit by 44.

The left portion 51 of the power filter circuit 40, which includes the inductors L1, L2, and L3 is identical to the capacitance multiplier configuration described in FIG. 4. The addition of op-amps in the right portion 52 of the power filter circuit 40, as described below, provides additional functionality to improve load regulation and noise performance.

In the positive half 53, the filtered output from the sub-circuit 43 is connected to one end of capacitor C2, which is coupled to the inverting input of op-amp U2A. The other end of C2 is connected to the output of the sub-circuit 43, so that C2 can be used to pass the AC component from the output of the sub-circuit 43 to U2A for amplification. The inverting input of U2A is connected to the junction of resistor R2 and capacitor C4, which together form a feedback network and are then connected to the output of U2A. Capacitor C4 allows AC coupling of feedback signals, while resistor R2 determines the gain of the amplifier. Via the series of R1 and C1, the output of U2A is connected to the junction of the emitter of Q2 and the base of Q1 within the sub-circuit 43. This configuration provides AC negative feedback to counteract variations in the output voltage. Capacitor C11, along with shunt voltage reference U1, provides a stable low-noise DC bias voltage for the non-inverting input of U2A, which is also connected to the output of the sub-circuit 43 via resistor R3. The other end of C11 or U1 is connected to the outgoing ground. U1 and its associated capacitor C11 further filter any high-frequency noise before it reaches the op-amp.

Similarly, in the negative half 54, the filtered output from the sub-circuit 44 is connected to one end of capacitor C22, which is coupled to the inverting input of op-amp U4A. The other end of C22 is connected to the output of the sub-circuit 44, so that C22 can be used to pass the AC component from the output of the sub-circuit 44 to U4A for amplification. The inverting input of U4A is connected to the junction of resistor R14 and capacitor C20, which together form a feedback network and are then connected to the output of U4A. Capacitor C20 allows AC coupling of feedback signals, while resistor R14 determines the gain of the amplifier. Via the series of R13 and C21, the output of U4A is connected to the junction of the emitter of Q3 and the base of Q4 within the sub-circuit 44. This configuration provides AC negative feedback to counteract variations in the output voltage. Capacitor C12, along with shunt voltage reference U3, provides a stable low-noise DC bias voltage for the non-inverting input of U4A, which is also connected to the output of the sub-circuit 44 via resistor R12. The other end of C12 or U3 is connected to the outgoing ground. U3 and its associated capacitor C12 further filter any high-frequency noise before it reaches the op-amp.

The addition of op-amps to provide AC negative feedback effectively reduces the AC impedance of the circuit, countering any AC variations that would otherwise occur due to changes in load conditions. This results in improved noise performance, better load regulation, and enhanced soft-start ramping of the output. This configuration may make the capacitance multiplier circuit particularly suitable for applications requiring precise, low-noise, and stable DC power supplies.

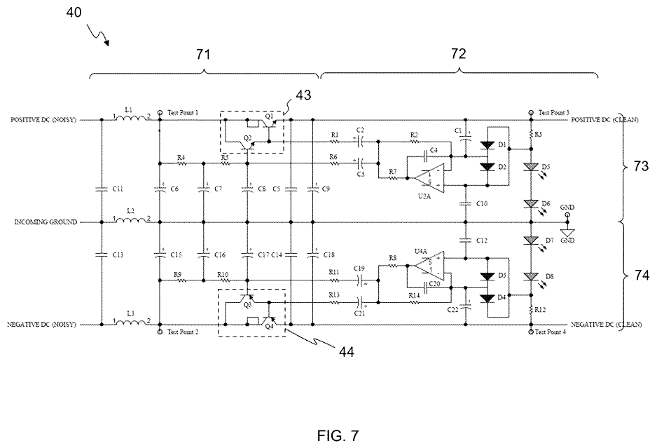

FIG. 6 illustrates a second variant of the power filter circuit 40 involving Darlington pairs for noise filtering. This circuit introduces additional negative feedback paths to further enhance the filter's performance at low frequencies. The circuit is divided into the positive half, indicated by 63, and the negative half, indicated by 64. Like in the circuit described in relation to FIG. 4, the positive Darlington pairs sub-circuit is represented by 43, while the negative Darlington pairs sub-circuit is represented by 44. The left portion 61 of the power filter circuit 40 is identical to the configuration in FIG. 4, except that parallel capacitors (C5 and C9, or C14 and C18) are used at the outputs of the capacitance multipliers instead of a single capacitor.

The introduction of additional negative feedback paths in this circuit provides significant improvements in both line and load regulation at frequencies below 100 Hz. The technique extends the line filter corner frequency by approximately an order of magnitude, leading to a potential 40 dB improvement in filtering performance at approximately 0.2 Hz. Similarly, load regulation can be enhanced by more than 20 dB at frequencies below 10 Hz. The feedback arrangement also introduces an impedance notch in the 40-60 Hz range, further improving rejection of mains-related noise. However, it should be understood that the precise degree of these improvements depends on multiple component values and circuit design considerations, particularly with respect to maintaining high-frequency stability. As a result, actual performance characteristics may vary across implementations based on component tolerances and design trade-offs.

The right portion of the power filter circuit 40, indicated as 62, introduces additional functionality to further enhance filtering performance, compared to the circuit described in relation to FIG. 5. The components in the context of op-amp U1A are the same with those described in relation to FIG. 5, except that there is an additional resistor R7 at the output of U1A and a further feedback signal path. In the positive half 63, the base of Q2 in the sub-circuit 43 receives the further negative feedback signal from R7 through the combination of capacitor C3 and resistor R6. Capacitor C3 allows AC signals at low frequencies to pass, while R6 determines the feedback gain. This feedback path helps to lower the effective filter corner frequency, improving low-frequency noise filtering without compromising stability (while the higher frequency feedback is shunted by capacitors C8 and C11).

Diodes D1 and D2 are included in the right portion 62 of the power filter circuit 40 as part of the positive half 63. These diodes are connected in series, with both ends connecting to the non-inverting input of U1A. The junction between D1 and D2 is tied to the inverting input of U1A to form a clamping network that stabilizes the feedback loop and limits voltage swing at the inverting input.

Similarly, in the negative half 64, the base of Q3 in the sub-circuit 44 receives a further negative feedback signal through the combination of capacitor C19 and resistor R11. Capacitor C19 enables low-frequency feedback, and R11 controls the gain of the feedback path. As in the positive half, high-frequency feedback is shunted by capacitor C17 and C13 to maintain circuit stability. Diodes D3 and D4 also form a clamping network for op-amp U4A.

Additionally, this circuit substitutes Zener diodes D5 and D6 in place of the shunt voltage references (U1 and U3 in FIG. 5). The Zener diodes D5 and D6 establish a DC bias for the non-inverting inputs of U1A and U4A. Resistors R15 and R16 are included to form low-pass filters with capacitors C10 and C12, respectively, to reduce the noise generated by the Zener diodes D5 and D6. The Zener diodes D5 and D6 may be replaced with other components, such as integrated shunt voltage references, low-current low-noise voltage regulators, or standard diodes or light-emitting diodes (LEDs), depending on the design requirements.

U1A and U4A provide AC negative feedback to the Darlington pairs sub-circuits 43 and 44, with their outputs connected to the junctions of Q2's emitter and base as well as Q1's base in the positive half, and Q3's emitter and base as well as Q4's base in the negative half. The feedback effectively reduces AC variations at the outputs while maintaining a stable DC bias. The outputs of the circuit are labeled as “Positive DC (Clean)” and “Negative DC (Clean)” and are accessible at test points labeled “Test Point 3” and “Test Point 4”, respectively. These enhancements make the circuit effective at filtering noise across a wide frequency range and stabilizing the output voltages for sensitive applications.

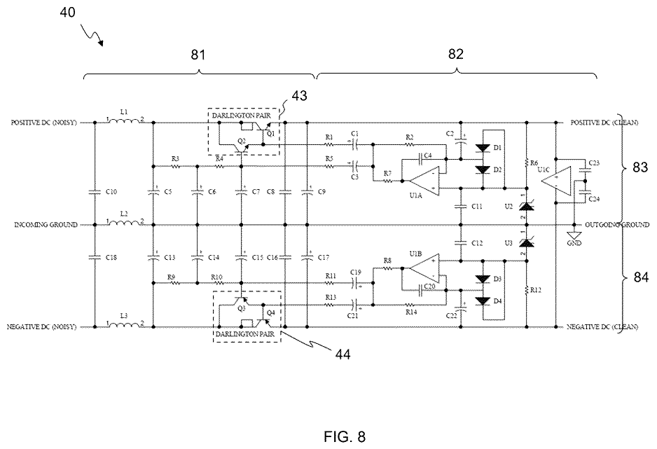

FIG. 7 illustrates a third variant of the power filter circuit 40 involving Darlington pairs for noise filtering. This circuit introduces the use of LEDs to establish a DC bias voltage for the op-amps, replacing the Zener diodes or shunt references used in other variants. The power filter circuit 40 is divided into the positive half, indicated by 73, and the negative half, indicated by 74. The positive Darlington pairs sub-circuit is represented by 43, while the negative Darlington pairs sub-circuit is represented by 44.

The left portion of the circuit, indicated by 71, is identical to the configuration in FIG. 6. The right portion of the circuit, indicated by 72, is almost identical to the configuration in FIG. 6, with the primary difference being the replacement of Zener diodes with LEDs to establish the DC bias voltage. In the positive half 73, diodes D5 and D6 are green LEDs with a typical forward voltage drop of approximately 2.5 volts each. The LEDs are connected in series, with their anode connected to one end of resistor R3 (also to the clamping network formed by D1 and D2) and their cathode connected to the ground. This arrangement, combined with the current supplied through resistor R3, establishes a DC bias voltage of approximately +5 volts across D5 and D6. The DC bias voltage is further low-pass filtered by capacitor C10 to provide stability and reduce noise before being supplied to op-amp U2A.

Similarly, in the negative half 74, diodes D7 and D8 are also green LEDs with a typical forward voltage drop of approximately 2.5 volts each. The LEDs are connected in series, with their anode connected to one end of resistor R12 (also to the clamping network formed by D3 and D4) and their cathode connected to ground. This configuration provides a DC bias voltage of approximately −5 volts across D7 and D8, which is further filtered by capacitor C12 before being supplied to op-amp U4A.

The use of LEDs as voltage references offers an alternative to the Zener diodes used in FIG. 6. This substitution may simplify the circuit and provides a stable, low-noise DC bias for the op-amps while maintaining the same functionality.

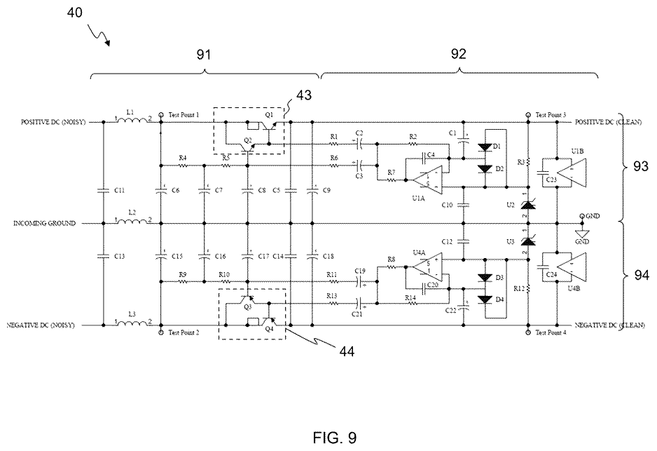

FIG. 8 illustrates a fourth variant of the power filter circuit 40 involving Darlington pairs for noise filtering. This circuit incorporates a dual op-amp and includes explicit power supply pins for the op amps, as well as bypass capacitors for stabilizing the power supplies. The circuit is divided into the positive half, indicated by 83, and the negative half, indicated by 84. The positive Darlington pairs sub-circuit is represented by 43, while the negative Darlington pairs sub-circuit is represented by 44.

The left portion of the circuit, indicated by 81, is identical to the configuration in FIG. 6. The right portion of the circuit, indicated by 82, is almost identical to the configuration in FIG. 6, in which the main difference relates to the inclusion of a dual op-amp U1C along with bypass capacitors C23 and C24. The power supply pins of U1C are explicitly shown in this circuit to clarify their role in powering the op-amp. The power to U1C is taken directly from the positive and negative supplies, with each of the bypass capacitors C23 and C24 connected between their respective power pins of U1C and the ground. Specifically, capacitor C23 is connected to the positive power pin of U1C, while capacitor C24 is connected to the negative power pin of U1C.

This configuration reduces the demands on the bias networks by drawing power for the op-amp directly from the filtered positive and negative supplies, potentially simplifying the circuit design. However, it may result in a lower power supply rejection ratio (PSRR), particularly with respect to noise from the opposite supply that the op-amp is stabilizing. To address this, bypass capacitors C23 and C24 are included to filter high-frequency noise and stabilize the op-amp's power rails. This arrangement balances simplicity with acceptable noise performance for applications requiring filtered and stabilized power.

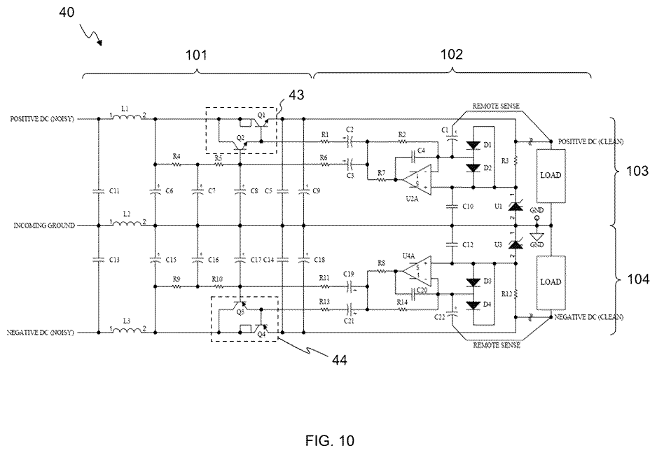

FIG. 9 illustrates a fifth variant of the power filter circuit 40 involving Darlington pairs for noise filtering. This circuit additionally incorporates two single op-amps U1B and U4B, each with explicit power pins and bypass capacitors C23 and C24, respectively, to further enhance noise filtering and stability. The circuit is divided into the positive half, indicated by 93, and the negative half, indicated by 94. The positive Darlington pairs sub-circuit is represented by 43, while the negative Darlington pairs sub-circuit is represented by 44.

The left portion of the circuit, indicated by 91, is identical to the configuration in FIG. 8. The right portion of the circuit, indicated by 92, is almost identical to the configuration in FIG. 8. The main difference lies in the use of two single op-amps (U1B and U4B) with explicit power connections. In this circuit, one of the power pins for each op-amp is connected to the ground instead of the opposite power supply polarity. This arrangement may avoid coupling effects that may arise from attaching the op-amp's power pins to opposite supply polarities, so as to address limitations associated with imperfect PSRR. While this design may introduce the requirement for more precise biasing to allow the op-amps (for avoiding clipping near the ground and increase output voltage levels), it can provide a stable and reliable filtering solution to maintain the advantages of enhanced noise rejection and load regulation.

FIG. 10 illustrates a sixth variant of the power filter circuit 40 involving Darlington pairs for noise filtering. This circuit incorporates “remote sense” lines to optimize the feedback points, reducing the impedance effects of printed circuit board (PCB) traces. The circuit is divided into the positive half, indicated by 103, and the negative half, indicated by 104. The positive Darlington pairs sub-circuit is represented by 43, while the negative Darlington pairs sub-circuit is represented by 44.

The left portion of the circuit, indicated by 101, is identical to the configuration in FIG. 6. The right portion of the circuit, indicated by 102, is also similar to the configuration in FIG. 6. The main difference in this circuit is the inclusion of “remote sense” lines in both the positive half 103 and the negative half 104. In the positive half 103, a remote sense line connects the feedback point of U2A to the load connected at the “Positive DC (Clean)” output via capacitor C1. Similarly, in the negative half 104, a remote sense line connects the feedback point of U4A to the load connected at the “Negative DC (Clean)” output via capacitor C22. These sense lines may allow the AC feedback signals to be taken directly from the load, thus bypassing the impedance effects of PCB traces.

This configuration compensates for voltage variations caused by current draw fluctuations in the connected load. By sensing the voltage at the load, the circuit may effectively reduce the combined impedance of the power filter and the PCB traces. This results in improved voltage stability and performance where low output impedance and precise regulation are desired.

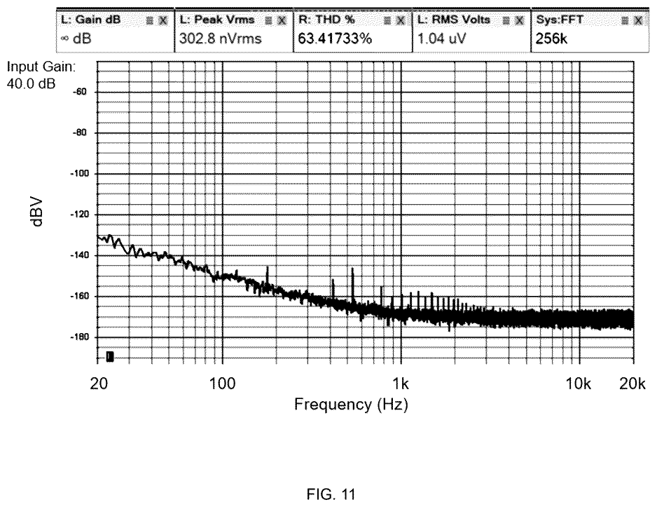

FIG. 11 illustrates an example of the measured voltage noise performance of one implementation of the disclosure, such as the example circuit of FIG. 7 or 9. The graph showcases the noise characteristics in terms of dBV across a range of frequencies. A significant measurement of 1.04 μV RMS noise demonstrates the circuit's ability to achieve low-noise performance, comparing favorably with existing chip-based voltage regulators.

Below 1 kHz, the noise performance is dominated by the 1/f noise (flicker noise) characteristics of the op-amp used in the circuit. This type of noise tends to increase at lower frequencies and is influenced by the specific choice of op-amp. Op-amps with a lower 1/f noise corner frequency may be selected if further reduction of low-frequency noise is required for specific applications.

At frequencies above 1 kHz, the measured noise may be limited by the resolution and sensitivity of the test equipment used. The results, however, still indicate an extremely low-noise performance. Additional artifacts visible at levels below −145 dB across various frequencies are primarily attributed to the noise floor and limitations of the test bench setup, rather than inherent characteristics of the power filter circuit.

Compared to commonly available voltage regulators, the disclosed power filter circuit achieves a substantial reduction in output noise. For reference, typical linear regulators such as the LM7815 specify output noise levels of approximately 150 μV at 15V, while other common regulators exhibit noise in the range of 450 μV at similar voltages. Based on these values, the disclosed circuit may provide at least a 40 dB improvement over widely used regulators. Additionally, fast Fourier transform (FFT) noise measurements above 1 kHz suggest that common regulators exhibit baseline noise levels in the range of −60 dB to −80 dB, which is 80-100 dB higher than that observed in the disclosed power filter circuit. A review of ultra-low noise linear voltage regulators shows that most commercially available devices operate below 7V and exhibit noise levels above 1.5 μV, with values up to 25 μV still considered ultra-low noise. In comparison, the disclosed power filter circuit can achieve 1.04 μV RMS noise measurement. However, it should be understood that variations in test conditions and measurement techniques across manufacturers may make direct comparisons challenging. The disclosed power filter circuit achieves noise performance that is competitive with, or superior to, many existing ultra-low noise voltage regulators while offering flexibility in voltage operation.

It should be understood that the implementations described herein are provided as illustrative examples, and are not intended to limit the scope of the disclosure. The specific configurations, components, and sub-circuits described in relation to the various figures are provided to demonstrate how the invention can be applied in practice. However, it is recognized that one skilled in the art can modify, adapt, or substitute these components and configurations without departing from the scope of the disclosure.

Different types of transistors may be used in the disclosed power filter circuit depending on specific design requirements, including cost, performance, or manufacturing considerations. Furthermore, the values and placement of resistors and capacitors in the circuit can be adjusted or optimized based on the intended application or the desired performance characteristics, such as noise reduction, load regulation, or frequency response. These modifications and variations are considered to be within the scope of the present disclosure.

It should also be noted that while op-amps are used in the embodiments described, equivalent sub-circuits formed from discrete components, such as transistors, resistors, and capacitors, may be implemented to achieve similar functionality. The choice between using integrated op-amps or discrete components may depend on factors such as performance requirements, available components, or cost considerations.

Furthermore, the labeling and designation of components across the various embodiments may differ to accommodate different designs. Despite such differences, the underlying principles and functionality of the disclosed power filter circuit remain consistent across all embodiments described herein. These variations and adaptations are likewise considered to fall within the scope of the disclosure.

The terminology used herein is for the purpose of describing particular embodiments only and is not intended to be limiting. Accordingly, as used herein, the singular forms “a”, “an”, and “the” are intended to include the plural forms as well, unless the context clearly indicates otherwise. It will be further understood that the terms “comprises” and “comprising”, when used in this specification, specify the presence of one or more stated features, integers, steps, operations, elements, and components, but do not preclude the presence or addition of one or more other features, integers, steps, operations, elements, components, and groups. Directional terms such as “top”, “bottom”, “upwards”, “downwards”, “vertically”, and “laterally” are used in the following description for the purpose of providing relative reference only, and are not intended to suggest any limitations on how any article is to be positioned during use, or to be mounted in an assembly or relative to an environment. Additionally, the term “connect” and variants of it such as “connected”, “connects”, and “connecting” as used in this description are intended to include indirect and direct connections unless otherwise indicated. For example, if a first device is connected to a second device, that coupling may be through a direct connection or through an indirect connection via other devices and connections. Similarly, if the first device is communicatively connected to the second device, communication may be through a direct connection or through an indirect connection via other devices and connections.

As used herein, the term “about” refers to an approximately +/−10% variation from a given value. It is to be understood that such a variation is always included in any given value provided herein, whether or not it is specifically referred to.

Use of language such as “at least one of X, Y, and Z”, “at least one of X, Y, or Z”, “at least one or more of X, Y, and Z”, “at least one or more of X, Y, and/or Z”, or “at least one of X, Y, and/or Z”, is intended to be inclusive of both a single item (e.g., just X, or just Y, or just Z) and multiple items (e.g., {X and Y}, {X and Z}, {Y and Z}, or {X, Y, and Z}). The phrase “at least one of” and similar phrases are not intended to convey a requirement that each possible item must be present, although each possible item may be present.

It is contemplated that any part of any aspect or embodiment discussed in this specification can be implemented or combined with any part of any other aspect or embodiment discussed in this specification, so long as such those parts are not mutually exclusive with each other.

The scope of the claims should not be limited by the embodiments set forth in the above examples, but should be given the broadest interpretation consistent with the description as a whole.

It should be recognized that features and aspects of the various examples provided above can be combined into further examples that also fall within the scope of the present disclosure. In addition, the figures are not to scale and may have size and shape exaggerated for illustrative purposes.

What is claimed is:

1. A power filter circuit comprising:
a capacitance multiplier configured to receive an input signal from a power supply, the capacitance multiplier including:
a low-pass filter; and
at least one Darlington pairs sub-circuit comprising two transistors; and
a feedback network configured to provide alternating current (AC)-coupled negative feedback from an output node of the capacitance multiplier to a base node of at least one of the two transistors in the Darlington pairs sub-circuit to enhance noise rejection in an output signal of the power filter circuit.

2. The power filter circuit of claim 1, wherein the low-pass filter comprises a plurality of resistors and a plurality of capacitors arranged to form a multi-pole low-pass filter.

3. The power filter circuit of claim 1, wherein the feedback network is configured to provide the AC-coupled negative feedback to respective base nodes of the two transistors of the at least one Darlington pairs sub-circuit.

4. The power filter circuit of claim 1, wherein the feedback network comprises at least one amplifier configured to amplify an AC component from the output node of the capacitance multiplier and inject the amplified AC component into the base node of the at least one of the two transistors in the Darlington pairs sub-circuit.

5. The power filter circuit of claim 4, wherein the feedback network comprises a coupling capacitor configured to pass the AC component from the output node of the capacitance multiplier to the amplifier.

6. The power filter circuit of claim 4, wherein the amplifier comprises an operational amplifier or an amplification stage formed from discrete components.

7. The power filter circuit of claim 4, wherein the amplifier is biased with a direct current (DC) using at least one of:
a Zener diode,
a light-emitting diode (LED), or
an shunt voltage reference.

8. The power filter circuit of claim 4, wherein the power filter circuit comprises a positive half and a negative half, each of the positive half and the negative half connecting to the power supply and including its corresponding capacitance multiplier and feedback network.

9. The power filter circuit of claim 8, wherein the feedback network further comprises an amplification sub-circuit that is powered by a positive supply voltage from the output node of the positive half and a negative supply voltage from the output node of the negative half.

10. The power filter circuit of claim 9, wherein the amplification sub-circuit comprises a dual operational amplifier in parallel with two capacitors connected in series, a junction of the two capacitors being grounded.

11. The power filter circuit of claim 9, wherein the amplification sub-circuit comprises two operational amplifiers each being in parallel with a capacitor, a junction of the two operational amplifiers being grounded.

12. The power filter circuit of claim 1, wherein the feedback network comprises at least one amplifier configured to amplify an AC component directly from a load of the power filter circuit through a remote sense line and a coupling capacitor, and inject the amplified AC component into the base node of the at least one of the two transistors in the Darlington pairs sub-circuit.

13. A method of operating a power filter circuit, the method comprising:
feeding an input signal from a power supply to a capacitance multiplier of the power filter circuit, the capacitance multiplier including a low-pass filter and at least one Darlington pairs sub-circuit comprising two transistors;
processing the input signal through the low-pass filter and the at least one Darlington pairs sub-circuit to generate a filtered signal;
providing the filtered signal at an output node of the capacitance multiplier to a feedback network of the power filter circuit to generate an AC-negative feedback; and
applying the AC-negative feedback to a base node of at least one of the two transistors in the at least one Darlington pairs sub-circuit to enhance noise rejection in an output signal of the power filter circuit.

14. The method of claim 13, wherein the low-pass filter comprises a plurality of resistors and a plurality of capacitors arranged to form a multi-pole low-pass filter.

15. The method of claim 13, further comprising applying the AC-coupled negative feedback to respective base nodes of the two transistors in the Darlington pairs sub-circuit.

16. The method of claim 13, further comprising:
amplifying an AC component of the filtered signal, from the output node of the capacitance multiplier, using an amplifier in the feedback network; and
injecting the amplified AC component into the base node of at least one of the two transistors in the Darlington pairs sub-circuit.

17. The method of claim 16, further comprising:
passing the AC component of the filtered signal through a coupling capacitor to the amplifier in the feedback network.

18. The method of claim 16, further comprising:
biasing the amplifier with a DC using at least one of:
a Zener diode;
a light-emitting diode (LED); or
a shunt voltage reference.

19. The method of claim 16, wherein the power filter circuit comprises a positive half and a negative half, each of the positive half and the negative half connecting to the power supply and including its corresponding capacitance multiplier and feedback network.

20. The method of claim 13, further comprising:
amplifying an AC component of the filtered signal, directly from a load of the power filter circuit through a remote sense line and a coupling capacitor, using an amplifier in the feedback network; and
injecting the amplified AC component into the base node of at least one of the two transistors in the Darlington pairs sub-circuit.
